(19) United States
(12) Patent Application Publication
(10) Pub. No.: US 2002/0092166 A1
(43) Pub. Date: Jul. 18, 2002

(54) HEAT PIPE AND METHOD AND APPARATUS FOR MAKING SAME

(76) Inventors: Paul F. Jacobs, Saunderstown, RI (US); Jeff Bullington, Albuquerque, NM (US)

Correspondence Address: PERMAN & GREEN, 425 POST ROAD, FAIRFIELD, CT, 06430, US

(21) Appl. No.: 09/760,160

(22) Filed: Jan. 12, 2001

(51) Int. Cl. H05K 7/20; F28D 15/00

(52) U.S. Cl. 29/890.032; 361/709; 165/104.26

(57) ABSTRACT

A planar heat sink, using heat pipe principals, is constructed by encapsulating a metalized heat fugitive plastic mandrel in a copper electroform bath and removing the plastic mandrel. The heat pipe chamber of the heat sink is constructed with a plurality of cruciform shaped vanes, wicking structures, for improved wetting and to prevent the formation of droplets. The plastic mandrel is injection molded having opposing negative front and back panels containing negative vanes. The core and cavity for the injection mold tool are formed by electroforming a machined aluminum plate which is etched by laser with the vane pattern.

### BACKGROUND OF THE INVENTION

Microprocessor chips continue to be manufactured with increased capacity and speed. These chips contain densely packed microcircuits demanding increased power consumption. The engineering and use of such chips have reached a point where the dissipation of heat from these units is a limiting factor. A need has, therefore, arisen for heat dissipating modules with greater efficiencies of operation. One promising approach is the adaptation of heat pipe concepts for the purpose of heat removal from microprocessor chips.

A heat pipe comprises a closed system of continuous evaporation and condensation of an operating fluid such as methyl alcohol (methanol). The heat pipe is positioned with one end near a source of heat and the other at a cooler ambient temperature. The methanol coats the internal surfaces of the heat pipe and, as the temperature differential increases between the ends of the heat pipe, the methanol at the hotter end vaporizes. The methane vapor flows towards the cooler end where it condenses and releases its heat of vaporization. In this manner a current of liquid is set up on the walls of the heat pipe towards the hotter end with the gas passing to the cooler end via a central channel. This circulation provides an efficient mechanism for removing heat.

In order to take advantage of this process in a device for dissipating heat from miniature components such as semiconductor chips, there is a requirement for a cost effective method of constructing heat sinks which will use this heat pipe cooling effect. An effort to develop such heat pipes was conducted at Sandia Laboratories using photolithographic etching of pure silicon wafers to construct a heat pipe having wicking structures in the heat pipe channel. The wicking structures are in the form of cruciform shaped vanes extending into the heat pipe channel to encourage wetting of the interior surfaces of the heat pipe with the methanol and eliminate the formation of isolated droplets. This will facilitate the capillary action required by the heat pipe heat transfer process.

It is the object of this invention to construct a heat sink suitable for dissipating heat from semiconductor chips and other devices in which the heat sink uses the heat transfer mechanism of a heat pipe. In particular it is an object of this invention to construct a heat pipe having a planar orientation for adaptation into environments having limited space.

### SUMMARY OF THE INVENTION

A miniature heat sink is designed to dissipate heat from a semiconductor chip or other small device. The heat sink utilizes the heat transfer capabilities of a heat pipe. Flat walls are joined to form a planar heat pipe having an interior heat transfer chamber in which a heat transfer medium such as methanol is inserted. Small vanes, in the range of a tenth of a millimeter to a millimeter in size, are constructed on the interior surfaces of the chamber to encourage capillary action and minimize beading of the fluid medium. The vanes are formed by electoforming over a metalized molded plastic mandrel. The heat sink comprises a pair of flat walls formed about the mandrel and joined about their periphery to enclose a internal heat transfer chamber. The chamber is evacuated and partially filled with a liquid, such as methanol, which has a high latent heat of vaporization. One end of the heat sink is provided with external fins extending outward from the heat sink to promote the dissipation of heat. Another end of the heat sink is constructed with provision for engagement with the component with which it is designed to engage and cool. As is well known, the methanol will evaporate as the heat of the component rises. The methanol vapor will travel towards the cool end through the chamber where it condenses into a liquid. The liquid travels by capillary action along the interior surfaces of the opposing walls of the heat sink. In this manner an effective flow of liquid and gaseous methanol is set up in which the fluid medium absorbs heat at the warm end of the heat sink and dissipates it at the cool end for as long as there is a temperature differential sufficient to initiate the flow. The cruciform shaped vanes which extend into the interior of the chamber effectively eliminate the formation of droplets of liquid on the walls which will hamper effective flow along the wall surface.

In order to manufacture large production quantities of the heat sinks of this invention at a reasonable price, it is necessary to produce low cost tools for electroforming the heat sinks. A plastic mandrel is constructed by injection molding a planar tool having appropriate vane cavities formed on both sides. The plastic mandrel is then metalized to allow the deposit of copper through electroforming.

Since the plastic mandrel is formed by injection molding, appropriate tooling must first be constructed for the injection molding process. To build the tools for forming the plastic mandrel, a tool of sheet aluminum is machined to the desired dimensions and laser marked with a series of mesoscale cruciform shaped vanes. This forms a negative element onto which a hard nickel layer is electroformed. The nickel layer is removed from the aluminum mandrel and backed with a structural material, for example an aluminum filled epoxy. This step generates a positive mold element for one side of the injection molded plastic mandrel.

The opposite side of the plastic mandrel requires a separate tool in which the vanes are offset from the vanes of the first side. Again a tool is constructed starting with a machined aluminum sheet laser etched with an offset pattern of vanes. The etched aluminum sheet is coated with nickel to form the mating mold element for forming the plastic mandrel. The two mold elements thus formed are assembled in a mold fixture for use in an injection molding process.

The resulting molded part is the plastic mandrel which is metalized in preparation for the final electroforming step. The metalized plastic mandrel is placed in an electroforming bath to allow its encapsulation by copper to form the heat sink. An appropriate sprue remains uncoated to allow the removal of the plastic mandrel, evacuation of the chamber formed thereby, and the insertion of an operational amount of a working fluid. In this manner a heat pipe style heat sink is constructed in an efficient and cost effective manner for a variety of applications.

### DESCRIPTION OF THE DRAWINGS

The invention is described in more detail below with reference to the attached drawing in which:

FIG. 1 is a side view of the heat sink of this invention;

FIG. 2a is a sectional view of the heat sink along section lines 2-2 in FIG. 1;

FIG. 2b is an enlarged view of a portion of the heat sink shown in FIG. 2a;

FIG. 3a is an enlarged view showing the offset of the vanes of the heat sink of this invention;

FIG. 3b is an enlarged view showing the dimensions of the vanes of the heat sink of this invention;

FIG. 4a partial view of the aluminum mandrels constructed in the process of this invention;

FIG. 4b is partial view of the injection molding tool constructed in the process of this invention;

FIG. 5 a sectional view of a portion of the injection mold constructed in the process of this invention;

FIG. 6 is a perspective view of the plastic mandrel constructed in the process of this invention; and

FIG. 7 is a block diagram of the steps of the method of this invention.

### DESCRIPTION OF THE PREFERRED EMBODIMENT

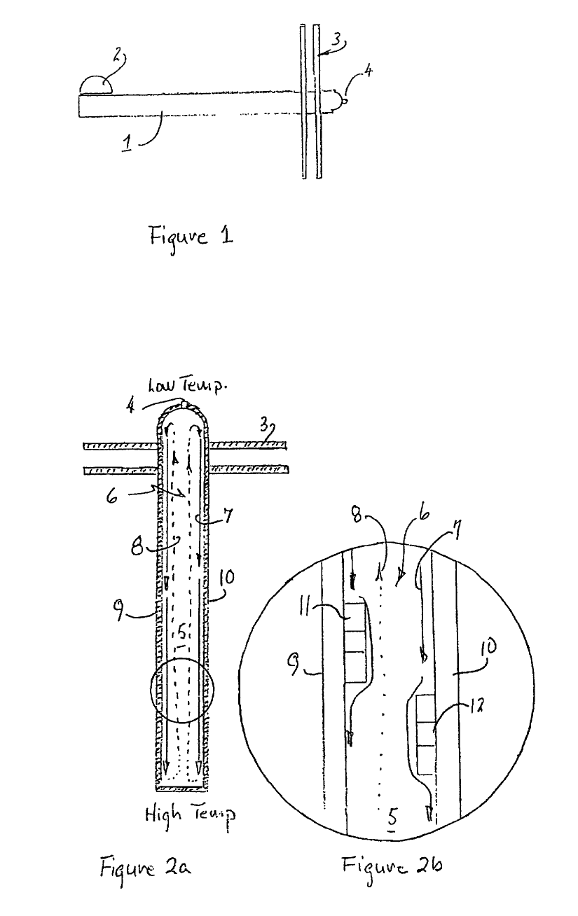

A heat sink 1 of this invention is shown in FIG. 1 in direct heat conductive association with a semiconductor chip 2. The heat sink 1 includes fins 3 to assist in radiating heat away from the heat sink 1. A nipple 4 is provided to allow access to the interior of the heat sink 1 and the insertion of a working fluid 6. In FIG. 2a, an internal chamber 5 is shown defined by joined walls 9 and 10. A working fluid 6, such as methanol, is inserted into the chamber 5 which is then sealed. The working fluid 6 wets the interior surface of the chamber 5 and is distributed over such surfaces by capillary action. In the preferred embodiment the walls 9 and 10 of the heat sink are constructed as flat panels of thin flexible heat conductive metal, such as copper. The finished heat sink will be planar in shape and flexible.

In operation the heat sink 1 is subjected to heat generated during the operation of semiconductor chip 2. As the temperature differential between the ends of the heat sink 1 increases, an amount of methanol begins to evaporate at the high temperature end. The methanol vapor 6 migrates towards the cooler end, as shown by dotted arrows 8 in FIGS. 2a and 2b. As the methanol vapor cools, it condenses and flows down the walls 9 and 10 of the heat sink 1, as shown by the arrows 7 in FIGS. 2a and 2b. In this manner, the heat sink operates as a heat pipe with all the heat dissipation advantages of such devices. The working fluid 6 absorbs its heat of vaporization at the heated end and releases it at the cooling end.

The efficient operation of the heat pipe depends on a consistent flow of fluid along the interior of walls 9 and 10. To insure this function, wicking vanes 11 and 12 are dispersed in offset patterns over the interior surfaces of walls 9 and 10 respectively. The wicking vanes 11 and 12 create a tortuous path for the fluid on the walls 9 and 10 and effectively prevent the formation of droplets which significantly impede the fluid flow and hinder the operation of the heat sink 1 as a heat pipe.

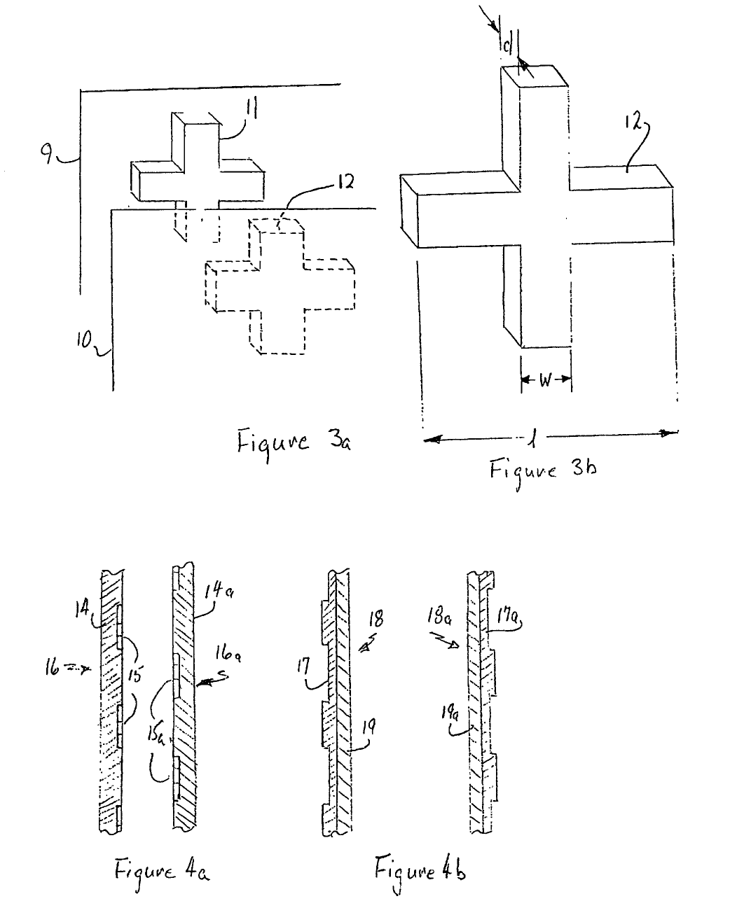

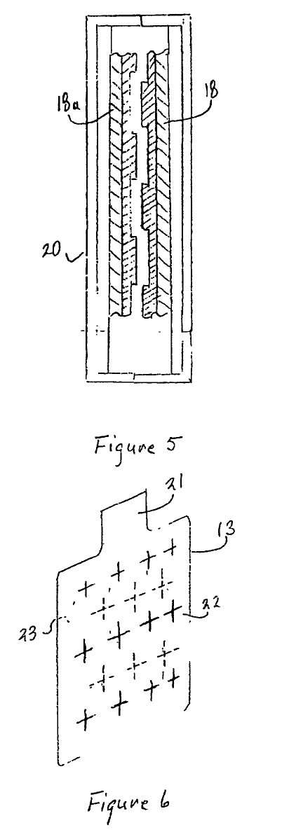

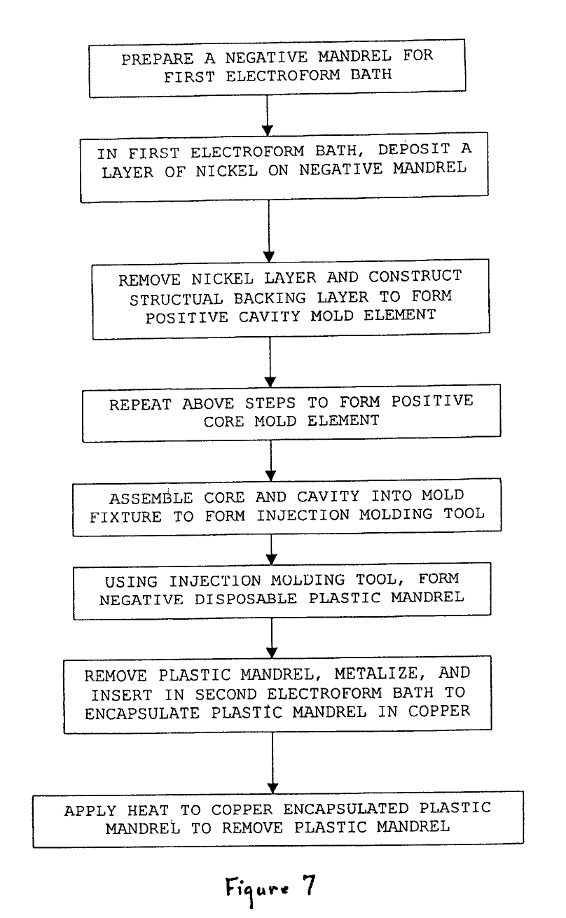

It has been found through research conducted at Sandia Laboratory that wicking structures formed in the shape of a cruciform, as shown in FIGS. 3a and 3b, and having a depth (d) of from 8 to 10 microns, a width (w) of around 20 microns and a length (l) of approximately 100 microns are particularly effective for this purpose. The work at Sandia, however, stopped short of a cost effective method of manufacturing these heat dissipating devices.

In the method of this invention a combination of electroforming and injection molding processes is used. The object of this method is to generate cost effective tools from which the heat sink can be economically constructed by electroforming. For this purpose a disposable plastic mandrel 13 is formed by injection molding. To achieve the pattern of outward extending vanes in the electroformed heat sink, the plastic mandrel 13 must be a negative tool.

Initially a set of injection molding tools is constructed by a first electroforming process. The tool for the injection molding of the disposable plastic mandrel therefore begins with the construction of a first electroform mandrel. As shown in FIG. 4a, an aluminum sheet 14 is machined to the desired size and laser etched with a pattern of multiple cavities 15 in the shape of cruciform vanes. Electroform mandrel 16, formed in this manner is subjected to the deposition of a nickel layer in an electroform bath.

Since walls 9 and 10 are constructed with differing patterns, a mandrel 16a is constructed in the same manner with a pattern of cavities 15a, laser etched into an aluminum sheet 14a, as shown in FIG. 4a. The patterns are offset a predetermined distance to eventually generate the sequence of opposing patterns of wicking structures, as illustrated in FIG. 3a.

The mandrels 16 and 16a are placed in an electroforming bath in which a layer of nickel 17 is deposited which will eventually form the active surface of the injection molding tools. The layer of nickel 17 is removed from mandrels and made rigid by the application of an epoxy impregnated with aluminum. In this manner injection molding tools 18 and 18a are formed having nickel active surfaces 17 and 17a and structural backing 19 and 19a.

To form the plastic mandrel 13, the tools 18 and 18a are arranged in a fixture 20 having all of the components required for injection molding. A plastic material such as low density polyethylene is injected into the assembled mold to construct plastic mandrel 13. In this manner large numbers of plastic mandrels may be constructed on a production basis at minimal cost.

Plastic mandrel 13 is shown in FIG. 6 and is constructed with a tab 21 to assist in subsequent steps and to insure a means of entry into the internal chamber 5 of the heat sink 1. Consistent with the molding process and the tools 18 and 18a, plastic mandrel 13 will have a pattern of cavities (negative) in the shape of tiny cruciform vanes. These patterns are molded on both sides 22 and 23 of the mandrel 13 slightly offset to create the labyrinth type path for the fluid as it flows, through capillary action, from the cool end of the heat sink to the warmer end. To prepare the plastic mandrel 13 for the electroform bath, the mandrel must be metalized. This can be accomplished on a batch basis by dipping the mandrels in a silver nitrate solution and subsequently in a reducing agent. A coating of silver nitrate, approximately 1 micrometer in thickness, is applied.

As illustrated in the block diagram of FIG. 7, the method of this invention, involves a somewhat convoluted, but effective, combination of steps to generate a series of mandrels and tools to construct the heat sink 1. With the end product being the interior chamber 5, the process begins with negative aluminum mandrels 16 and 16a. Using the mandrels 16 and 16a, injection mold core and cavity 18 and 18a are formed by a first electroforming process. The first electroforming process coats mandrels 16 and 16a with active surface layers 17 and 17a. The active surface layers are removed from the mandrels 16 and 16a and are structurally backed with aluminum filled epoxy layers 19 and 19a. At this point, the injection molding tools 18 and 18a are positive representations of the final product. After assembling the tools 18 and 18a in a mold fixture, heat fugitive plastic mandrel 13 may be produced in quantity and present a negative active surface for the final electroforming step.

To complete the process, a batch of mandrels 13 are placed in a continuous copper electroforming bath to encapsulate the mandrel in a copper coating. The electroforming process is maintained for sufficient time to allow the deposition of a copper coating of between 0.015 to 0.030 inches, approximately 10 to 20 hours. A portion of the tab 21 is masked to provide an entry to the interior of the heat sink 1. Since the mandrel 13 is plastic, it is readily removed from the electroformed heat sink structure by subjecting the heat sink to further heat. This may be accomplished by placing the assembly in a hydrogen reduction furnace and raising the temperature to 500° C. A copper heat sink is thus formed having walls which define an interior heat transfer chamber into which liquid methanol is injected by means of a syringe or other device. Other working fluids which may be used are ethanol and isopropyl alcohol. After the chamber is sealed the heat sink is complete and will function as a planar heat pipe.

Although the invention is described for use with semiconductor components, it will be adaptable to many different uses. The planar shape of the resulting heat sink and its method of manufacture will allow the generation of a line of thin flat heat sinks which will be flexible in the thicknesses obtainable. This is especially true of heat sinks made of copper according to the method of this invention. The heat sink of this invention is essentially a low cost, flexible heat plate having the operational characteristics of a heat pipe and will have many different uses, for example, thermal camouflage, clothing, electronic systems cooling, among others.

In this manner large production quantities of the thin, planar, flexible heat sinks, which employ heat pipe principals, can be manufactured in an inexpensive may.

We claim:

1. A heat sink for conducting heat away from a source of heat for dissipation comprising:
a heat transfer chamber enclosed by walls constructed of a heat conductive metal, said chamber containing a working fluid which wets the walls of the chamber from a first end to a second end of the chamber, said working fluid evaporating and thereby absorbing heat, when said first end is adjacent said heat source and flowing away from said heat source in a gaseous form, said flow causing a migration by capillary action of said fluid towards said first end and of said gas away from said first end, said gas condensing to a fluid at said second end, and thereby releasing heat;
said walls of said chamber constructed with opposing patterns of wicking structures extending into said chamber said opposing patterns being offset to form a tortuous path for fluid flow;
said walls being formed by encapsulating a heat fugitive mandrel in an electroforming bath.

2. A heat sink for conducting heat away from a source of heat for dissipation as described in claim 1 wherein said heat sink comprises a flat metal panel constructed of a flexible heat conductive metal.

3. A heat sink for conducting heat away from a source of heat for dissipation, as described in claim 1, wherein said heat conductive metal is copper.

4. A heat sink for conducting heat away from a source of heat for dissipation, as described in claim 1, wherein said heat fugitive mandrel is a planar shaped injection molded plastic mandrel constructed with negative impressions of said wicking structures.

5. A method for constructing a planar heat sink operable according to the principals of a heat pipe, said heat sink having an enclosed heat transfer chamber containing a working fluid, said chamber defined by walls, said walls constructed with a pattern of wicking structures extending into said chamber to form a tortuous path for said working fluid, said method comprising the steps of:
injection molding a planar shaped mandrel having at least one side impressed with cavities representing said pattern of wicking structures, said mandrel molded from a heat fugitive plastic material;
metalizing said mandrel;
inserting said mandrel into an electroform bath to encapsulate said mandrel with a coating of heat conductive metal and form a heat sink;
heating said heat sink to evacuate the mandrel and form said heat transfer chamber therein, said chamber having wicking structures on said walls extending into said chamber;
inserting a predetermined quantity of working fluid in said chamber and sealing said chamber.

6. A method for constructing a planar heat sink operable according to the principals of a heat pipe, said heat sink having an enclosed heat transfer chamber containing a working fluid, said chamber defined by walls, said walls constructed with a pattern of wicking structures extending into said chamber to form a tortuous path for said working fluid, said method as described in claim 5, further comprising the steps of:
constructing a first mandrel from a flat metal panel and machining said panel to predetermined dimensions, said first mandrel having a pattern of cavities constructed therein, said first pattern of cavities representing said wicking structures;
constructing a second mandrel from a flat metal and machining said panel to predetermined dimensions, said second mandrel having a second pattern of cavities representing said wicking structures, said wicking structures of said second pattern being offset from said wicking structures of said first pattern; and
coating said first and second mandrels with a hard metal in an electroforming bath to form an active surface of a mold element used in injection molding of said plastic mandrel.

7. A method for constructing a planar heat sink operable according to the principals of a heat pipe, said heat sink having an enclosed heat transfer chamber containing a working fluid, said chamber defined by walls, said walls constructed with a pattern of wicking structures extending into said chamber to form a tortuous path for said working fluid, said method as described in claim 6, further comprising the steps of:
constructing an active surface for a first mold element by the coating of said first metal mandrel and applying a structural backing thereto;
constructing an active surface for a second mold element by the coating of said second metal mandrel and applying a structural backing thereto; and
assembling said first and second mold elements in a mold fixture for injection molding said plastic mandrel.

8. A method for constructing a planar heat sink operable according to the principals of a heat pipe, said heat sink having an enclosed heat transfer chamber containing a working fluid, said chamber defined by walls, said walls constructed with a pattern of wicking structures extending into said chamber to form a tortuous path for said working fluid, said method as described in claim 6, wherein said pattern of cavities are constructed by etching said first and second mandrels with a laser.

9. A method for constructing a planar heat sink operable according to the principals of a heat pipe, said heat sink having an enclosed heat transfer chamber containing a working fluid, said chamber defined by walls, said walls constructed with a pattern of wicking structures extending into said chamber to form a tortuous path for said working fluid, said method as described in claim 7, wherein said active surfaces are formed of nickel and said backing is formed of aluminum filled epoxy.

10. A method for constructing a planar heat sink operable according to the principals of a heat pipe, said heat sink having an enclosed heat transfer chamber containing a working fluid, said chamber defined by walls, said walls constructed with a pattern of wicking structures extending into said chamber to form a tortuous path for said working fluid, said method as described in claim 7, wherein said first and second metal mandrels are constructed having a negative representation of said wicking structures, said first and second mold elements are constructed having a positive representation of said wicking structures, and said first and second sides of said plastic mandrel are constructed having a negative representation of said wicking structures.

11. Apparatus for constructing a planar heat sink operable according to the principals of a heat pipe, said heat sink having an enclosed heat transfer chamber containing a working fluid, said chamber defined by walls, said walls constructed with a pattern of wicking structures extending into said chamber to form a tortuous path for said working fluid, said apparatus comprising:
an injection molded mandrel formed as a flat panel of heat fugitive plastic, said mandrel being coated with a metalizing solution to allow the coating of said mandrel in an electroforming bath, said mandrel having first and second opposing sides;
wherein said first side is constructed with a first pattern of cavities representing said wicking structures; and
wherein said second side is constructed with a second pattern of cavities representing said wicking structures, said wicking structures of said second pattern being offset from said wicking structures of said first pattern.

12. Apparatus for constructing a planar heat sink operable according to the principals of a heat pipe, said heat sink having an enclosed heat transfer chamber containing a working fluid, said chamber defined by walls, said walls constructed with a pattern of wicking structures extending into said chamber to form a tortuous path for said working fluid, said apparatus as described in claim 11, further comprising:
a first mandrel constructed of metal and machined to a flat panel of predetermined dimensions, said first mandrel having a pattern of cavities constructed therein, said first pattern of cavities representing said wicking structures; and
a second mandrel constructed of metal and machined to a flat panel of predetermined dimensions, said second mandrel having a second pattern of cavities representing said wicking structures, said wicking structures of said second pattern being offset from said wicking structures of said first pattern; and
wherein said first and second mandrels are coated with a hard metal in an electroforming bath to form an active surface of a mold element used in injection molding of said plastic mandrel.

13. Apparatus for constructing a planar heat sink operable according to the principals of a heat pipe, said heat sink having an enclosed heat transfer chamber containing a working fluid, said chamber defined by walls, said walls constructed with a pattern of wicking structures extending into said chamber to form a tortuous path for said working fluid, said apparatus as described in claim 12, further comprising:
a first mold element having an active surface formed by the coating of said first metal mandrel and having a structural backing applied thereto;
a second mold element having an active surface formed by the coating of said second metal mandrel and having a structural backing applied thereto; and
wherein said first and second mold elements are assembled in a mold fixture for injection molding said plastic mandrel.

14. Apparatus for constructing a planar heat sink operable according to the principals of a heat pipe, said heat sink having an enclosed heat transfer chamber containing a working fluid, said chamber defined by walls, said walls constructed with a pattern of wicking structures extending into said chamber to form a tortuous path for said working fluid, said apparatus as described in claim 13, wherein said first and second metal mandrels are constructed having a negative representation of said wicking structures, said first and second mold elements are constructed having a positive representation of said wicking structures, and said first and second sides of said plastic mandrel are constructed having a negative representation of said wicking structures.

15. Apparatus for constructing a planar heat sink operable according to the principals of a heat pipe, said heat sink having an enclosed heat transfer chamber containing a working fluid, said chamber defined by walls, said walls constructed with a pattern of wicking structures extending into said chamber to form a tortuous path for said working fluid, said apparatus as described in claim 13, wherein said pattern of cavities are constructed by etching said first and second mandrels with a laser.

16. Apparatus for constructing a planar heat sink operable according to the principals of a heat pipe, said heat sink having an enclosed heat transfer chamber containing a working fluid, said chamber defined by walls, said walls constructed with a pattern of wicking structures extending into said chamber to form a tortuous path for said working fluid, said apparatus as described in claim 13, wherein said active surfaces are formed of nickel and said backing is formed of aluminum filled epoxy.
